(19) United States
(12) Patent Application Publication
(10) Pub. No.: US 2016/0073540 A1
(43) Pub. Date: Mar. 10, 2016

(54) ELECTRONIC CARD HOLDER

(71) Applicant: HON HAI PRECISION INDUSTRY CO., LTD., New Taipei (TW)

(72) Inventor: SHAO-HAN CHANG, New Taipei (TW)

(21) Appl. No.: 14/526,194

(22) Filed: Oct. 28, 2014

(30) Foreign Application Priority Data
Sep. 10, 2014 (CN) 201410457062.5

(51) Int. Cl. H05K 7/14

(52) U.S. Cl. CPC H05K 7/1427

(57) ABSTRACT

An electronic card holder includes a housing, and a tray configured to receive an electronic card. The housing defines an opening, and the tray can be assembled in the housing by passing through the opening. Two recesses can be respectively defined on both sides of the tray. The electronic card holder further includes two holding members, a popup coupled to the two holding members, and a magnet located out of the housing. The two holding members can be respectively coupled to the two recesses, and can be configured to fasten the tray. The magnet relieves the tray from the holding members in coordination with the popup. The present disclosure can realize that the electronic card is easily removed from the housing.

### FIELD

The subject matter herein generally relates to an electronic card holder, and particularly to an electronic card holder with a release for inserting or ejecting an electronic card smoothly.

### BACKGROUND

Nowadays, electronic card holders are widely used in computers, mobile phones, cameras, et al to receive and hold electronic cards, such as a subscriber identity module (SIM) card or a flash memory card.

### BRIEF DESCRIPTION OF THE DRAWINGS

Implementations of the present technology will now be described, by way of example only, with reference to the attached figures.

FIG. 1 is an isometric view of an embodiment of an electronic card holder.

FIG. 2 is an exploded, perspective view of the electronic card holder of FIG. 1.

FIG. 3 is cross-sectional view of the electronic card holder taken along line III-III of FIG. 1.

FIG. 4 is cross-sectional view of the electronic card holder, showing the operating state of the electronic card holder of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising”, when utilized, means “including, but not necessarily limited to”; it specifically indicates open-ended inclusion or membership in the so-described combination, group, series and the like.

The present disclosure is described in relation to an electronic card holder.

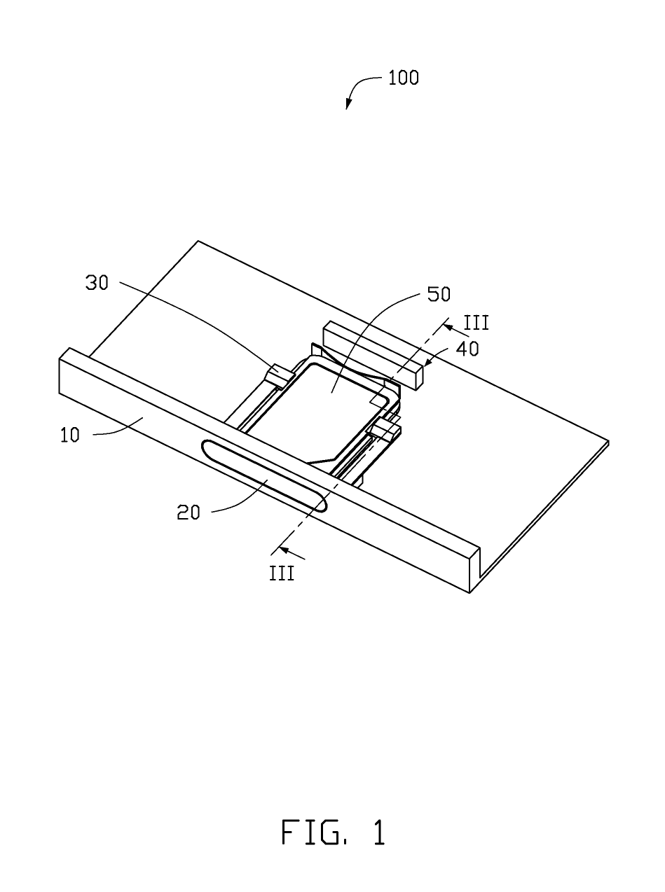

FIG. 1 illustrates an isometric view of an embodiment of an electronic card holder 100. The electronic card holder 100 can include a housing 10, a tray 20, a plurality of holding members 30; a popup 40, and an electronic card 50. The electronic card 50 can be a subscriber identity model (SIM) card, or a secure digital memory (SD) card, etc. In the illustrated embodiment, the electronic card holder 100 can include two holding members 30, and the two holding members 30 can be positioned on both sides of the tray 20. The two holding members 30 can be configured to fasten the tray 20 into the housing 10. The popup 40 can be assembled in the housing 10, and can resist against the tray 20. The popup 40 can be configured to eject the tray 20 from the housing 10. In operation, the electronic card holder 100 also includes other function modules, such as a printed circuit board (PCB), a conductive sheet, etc.

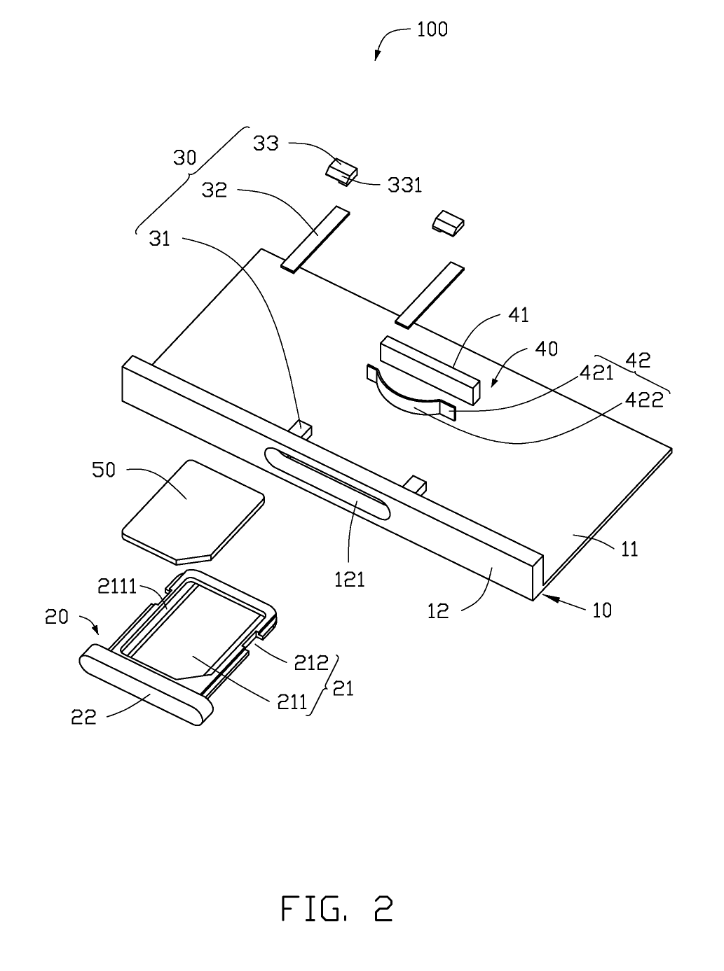

FIG. 2 illustrates a partially exploded, perspective view of the electronic card holder 100. The housing 10 can include a bottom plate 11 and a sidewall 12 extending from the bottom plate 11. The bottom plate 11 can be substantially rectangular, and can be perpendicular to the sidewall 12. The sidewall 12 can define an opening 121, and a cross-section of the opening 121 can be substantially bar-shaped. In at least one embodiment, the housing 10 can be made of metal material without magnetic conductivity, such as austenitic stainless steel, copper, aluminum alloy, etc. The housing 10 can also be made of plastic material.

The tray 20 can be coupled to the opening 121. In operation, the tray 20 can slide along a horizontal direction relative to the opening 121. The tray 20 can include a support 21 and a pressing portion 22 connected to the support 21. The support 21 can be substantially rectangular. The pressing portion 22 can be substantially bar-shaped, and can be coupled to the opening 121. In operation, when the tray 20 is inserted into the housing 10, the pressing portion 22 can completely plug the opening 121, and there is no gap between the pressing portion 22 and the opening 121, so the electronic card holder 100 can be substantially waterproof.

A through hole 211 can be defined on the support 21, and a supporting surface 2111 can be defined around the through hole 211. The supporting surface 2111 can be configured to receive the electronic card 50. In operation, the electronic card 50 can be connected to the PCB (not shown). Two recesses 212 can be defined on both sides of the support 21, and can be respectively coupled to the two holding members 30.

Each of the two holding members 30 can include a fixed platform 31, a first elastic element 32, and a fixture block 33. The fixed platform 31 can be a cube, and can be assembled on the bottom plate 11. Two fixed platforms 31 can be respectively positioned on both ends of the opening 121. The first elastic element 32 can be a rectangular sheet. One end of the first elastic element 32 can be connected to the fixed platform 31; the other end of the first elastic element 32 can be connected to the fixture block 33. The fixture block 33 can have the same size as each of the two recesses 212. A cross-section of the fixture block 33 can be trapezoidal. The fixture block 33 can include an inclined plane 331, and the inclined plane 331 can directly face the opening 121. In the illustrated embodiment, the first elastic element 32 and the fixture block 33 can be made of metal material with magnetic conductivity, such as iron, or magnets, etc.

The popup 40 can be assembled to the bottom plate 11, and can directly face the opening 121. The popup 40 can include a base portion 41 assembled to the bottom plate 11, and a second elastic element 42 assembled to the base portion 41. The base portion 41 can be cubiform, and the second elastic element 42 can be rectangular sheet. The second elastic element 42 can include mount 421 connected to the base portion 41, and a resisting portion 422 connected to the mount 421. The resisting portion 422 can be bow-shaped. In operation, when the tray 20 is inserted into the housing 10, the resisting portion 422 can press against the support 21. In the illustrated embodiment, two mounts 421 can be respectively connected to two ends of the resisting portion 422. One mount 421 can be connected to the base portion 41, and the other mount 421 can be free. When the resisting portion 422 is compressed by the tray 20, the mount 421 can extend along the base portion 41, improving resistance to compression.

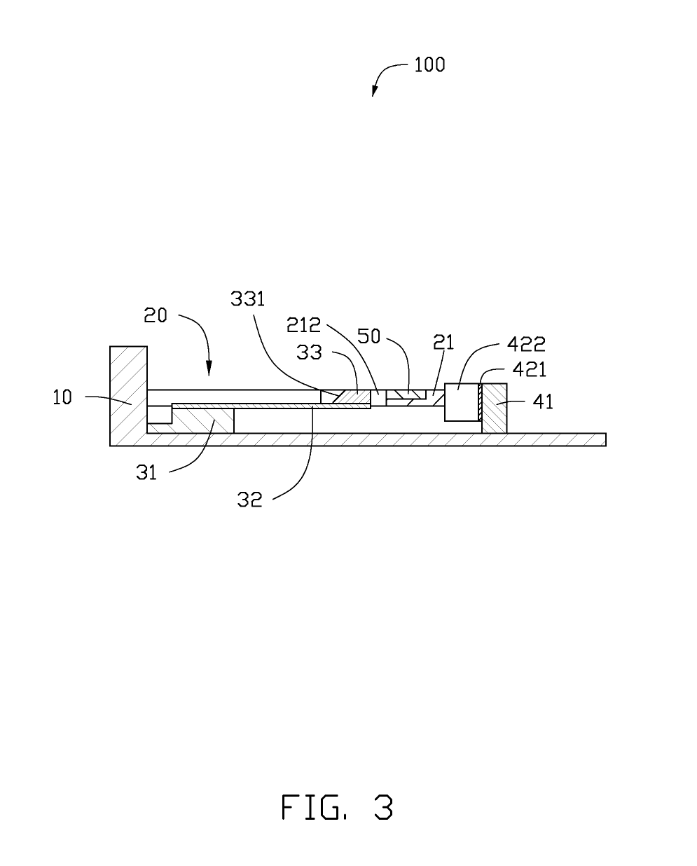

FIG. 3 illustrates a cross-sectional view of the electronic card holder 100. When the tray 20 is inserted into the housing 10, the support 21 can resist against the inclined plane 331, compressing the tray 20, and sliding the fixture block 33 to the bottom of the supporting portion 21 along the inclined plane 331. Then, the fixture block 33 can drop into the corresponding recess 212.

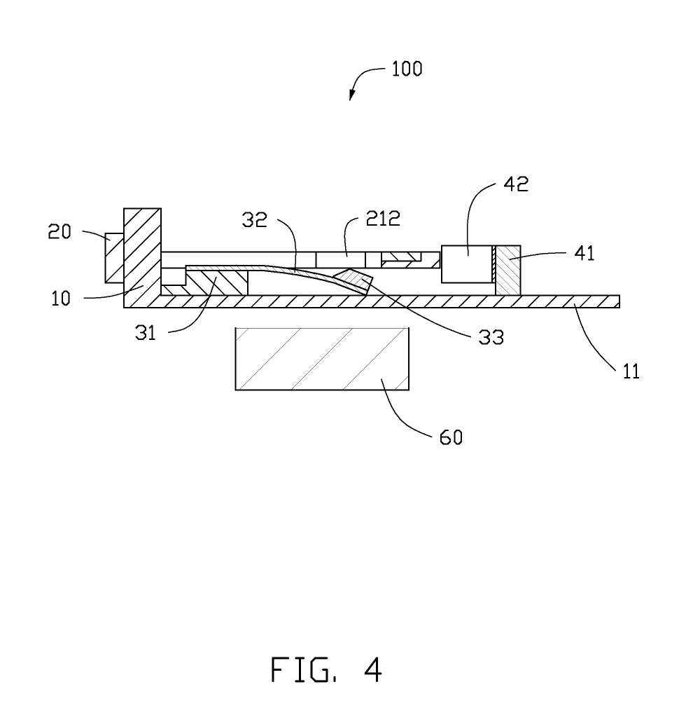

FIG. 4 illustrates that the electronic card holder 100 further includes a magnet 60. When the tray 20 is ejected from the housing 10, the magnet 60 can be positioned below the housing 10, corresponding to the fixture block 33. The fixture block 33 is attracted by the magnetic field of the magnet 60 and can be removed from the corresponding recess 212. The elastic element 42 can urge the tray 20 to allow removal from the housing 10. In at least one embodiment, a magnetic field of the magnet 60 can be greater than a restoring force of the first elastic element 32.

If the electronic card 50 needs to be inserted into the housing 10, the electronic card 50 can be received in the supporting surface 2111 first. Then the tray 20 can be assembled in the housing 10 through the opening 11, and the fixture block 33 can be coupled to the corresponding recess 212. The resisting portion 422 can urge the support 21 of the tray 20. Thereby the electronic card 50 can be mounted in the housing with the electronic card holder 100.

If the electronic card 50 needs to be ejected from the housing 10, the magnet 60 can be positioned below the housing 10, and can corresponded to the fixture block 33 first. The magnet 60 can attract the fixture block 33, and the fixture block 33 can be removed from the corresponding recess 212. The elastic element 42 can urge the tray 20 to be removed from the housing 10. So it is convenient to replace the electronic card 50.

The electronic card holder 100 can lock the electronic card 50 in the housing 10 by the two holding members 30. The popup 40 can eject the electronic card 50 from the housing 10 in coordination with the magnet 60. So it is convenient to remove the electronic card 50. Meanwhile, the pressing portion 22 of the tray 20 can be coupled to the opening 121, and there is no gap between the pressing portion 22 and the opening 121. So the electronic card holder 100 can be substantially waterproof.

The embodiments shown and described above are only examples. Many details are often found in the art such as the other features of an electronic card holder. Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size, and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An electronic card holder comprising:
a housing comprising:
an opening defined on the housing;
a tray comprising:
a support configured to receive an electronic card, wherein a plurality of recesses are defined on both sides of the support, and
a pressing portion connected to the support and coupled to the opening;
a plurality of holding members assembled in the housing and positioned adjacent to the opening, wherein the plurality of holding members are configured to fasten the tray in coordination with the plurality of recesses;
a popup assembled in the housing and configured to resist against the tray; and
a magnet located out of the housing, wherein the of magnet relieves the tray from the plurality of holding members, in coordination with the popup.

2. The electronic card holder as claimed in claim 1, wherein each of the plurality of holding members comprises a fixed platform, a first elastic element, and a fixture block, the fixed platform is positioned on side of the opening, one end of the first elastic element is connected to the fixed platform, the other end of the first elastic element is connected to the fixture block, the fixture block is coupled to the corresponding recess.

3. The electronic card holder as claimed in claim 2, wherein the fixture block comprises an inclined plane, and the support resists against the inclined plane.

4. The electronic card holder as claimed in claim 2, wherein the first elastic element and the fixture block are made of metal material with magnetic conductivity.

5. The electronic card holder as claimed in claim 1, wherein the housing comprises a bottom plate and a sidewall extended from the bottom plate, and the opening is defined on the sidewall.

6. The electronic card holder as claimed in claim 5, wherein the popup comprises a base portion assembled to the bottom plate, and a second elastic element connected to the base portion.

7. The electronic card holder as claimed in claim 6, wherein the second elastic element comprises mount connected to the base portion and a resisting portion connected to the mount, the resisting portion elasticity presses against the pressing portion of the tray.

8. The electronic card holder as claimed in claim 7, wherein the second elastic element comprises two mounts respectively connected to ends of the resisting portion, one mount is connected to the base portion, and the other mount is free.

9. The electronic card holder as claimed in claim 1, wherein the pressing portion completely plugs up the opening.

10. The electronic card holder as claimed in claim 1, wherein a through hole is defined on the support, a supporting surface is defined around the through hole, the supporting surface is configured to supporting the electronic card.

11. The electronic card holder as claimed in claim 1, wherein the housing is made of metal material without magnetic conductivity or plastic material.
